(19) United States
(12) Patent Application Publication
(10) Pub. No.: US 2025/0098116 A1
(43) Pub. Date: Mar. 20, 2025

(54) THERMALLY CONDUCTIVE BOARD

(71) Applicant: TCLAD TECHNOLOGY CORPORATION, TOUFEN CITY (TW)

(72) Inventors: KAI-WEI LO, Zhubei City (TW); Cheng Yi Lin, New Taipei City (TW); KUAN-YU CHEN, Taipei City (TW)

(21) Appl. No.: 18/442,647

(22) Filed: Feb. 15, 2024

(30) Foreign Application Priority Data
Sep. 18, 2023 (TW) 112135446

(51) Int. Cl. H05K 7/20

(52) U.S. Cl. CPC H05K 7/2039

(57) ABSTRACT

A thermally conductive board includes a top metal layer, a bottom metal layer, and an electrically insulating but thermally conductive layer (for simplification hereinafter referred to as “thermally conductive layer”) laminated between the top metal layer and the bottom metal layer. The thermally conductive layer includes a polymer matrix and a thermally conductive filler dispersed in the polymer matrix. The polymer matrix includes an epoxy-based composition consisting of epoxy and chlorine-containing impurities. The chlorine content of the thermally conductive layer is lower than 300 ppm.

### BACKGROUND OF THE INVENTION

### (1) Field of the Invention

The present application relates to a thermally conductive board, and more specifically, to a thermally conductive board with good weather resistance.

### (2) Description of the Related Art

In order to manufacture an electronic apparatus with specific functions, various electronic components within the electronic apparatus are assembled onto a substrate. This substrate serves as a carrier for mounting the electronic components, allowing these electronic components to be secured and electrically connected to an external power source. However, these electronic components generate heat during operation, and an excessive accumulation of heat could affect the normal operation of the electronic apparatus. To address the issue of heat accumulation, there are generally two approaches: the first is to add additional heat dissipation components outside the substrate, such as a heat sink, fan, thermal paste, or other heat dissipation components beyond the substrate; the second is to directly enhance the heat-conductive characteristics of the substrate by manufacturing it as a thermally conductive board with excellent thermal conductivity.

For the second approach mentioned above, the thermally conductive board typically consists of two metal layers with a thermally conductive layer laminated between them before the formation of a wiring layer. The top metal layer can be processed to form the wiring layer, while the bottom metal layer serves as a base substrate for thermal conduction, facilitating the dissipation of heat to the external environment. The thermally conductive layer is an electrically insulating layer with good thermal conductivity and low coefficient of thermal expansion (CTE). Conventionally, the thermally conductive layer is made of at least one resin and at least one thermally conductive filler. Improvements in the thermally conductive layer generally focus on the selection of the types of the resin and thermally conductive filler, attempting to achieve the optimal combination of one or more resins and one or more thermally conductive fillers. However, this approach faces the challenge of high complexity in formulation design. For instance, with change of the type of any one of the components (either resin or thermally conductive filler), it is necessary to consider the compatibility of that component with others and address numerous issues at the interface between it and the metal layer. Even after resolving the compatibility and interface issues, achieving the optimal proportion in the formulation remains necessary. If there is more than one type of the selected resin (or thermally conductive filler), the complexity of achieving the optimal proportion increases significantly, not to mention the addition of other additives commonly used in the industry alongside the resin and thermally conductive filler. Moreover, the types of electronic products are becoming increasingly diverse, and the complexity of the environments where they are used is also on the rise. Therefore, the performance of the thermally conductive board needs to be enhanced under the harsh environments. For example, copper ion migration is commonly observed in the conventional thermally conductive board during high temperature high humidity bias test (HHBT). This phenomenon compromises the electrical insulation of the thermally conductive board, accompanied by several adverse effects on its voltage endurance and other physical/chemical properties.

Obviously, the formulation design and weather resistance of the thermally conductive board need immediate improvements.

### SUMMARY OF THE INVENTION

The present invention provides a thermally conductive board. The thermally conductive board is a layered structure, having a top metal layer, a bottom metal layer, and an electrically insulating but thermally conductive layer laminated between the top metal layer and the bottom metal layer. The electrically insulating but thermally conductive layer includes a polymer matrix and a thermally conductive filler, thereby providing excellent electrical insulation and thermal conductivity. In the present invention, the major constituent of the polymer matrix is an epoxy-based composition. By precisely controlling the chlorine content in the epoxy-based composition, the thermally conductive board can exhibit excellent weather resistance.

In accordance with an aspect of the present invention, a thermally conductive board includes a top metal layer, a bottom metal layer, and an electrically insulating but thermally conductive layer laminated between the top metal layer and the bottom metal layer. The electrically insulating but thermally conductive layer includes a polymer matrix and a thermally conductive filler dispersed in the polymer matrix. The polymer matrix includes an epoxy-based composition consisting of epoxy and chlorine-containing impurities, wherein the epoxy is the main product obtained by a synthesis using epichlorohydrin and a dihydric phenol as raw materials, and the chlorine-containing impurities are the unreacted epichlorohydrin and by-products produced from the synthesis process. In addition, the chlorine-containing impurities has a chlorine content less than 300 ppm.

In an embodiment, the chlorine content of the chlorine-containing impurities ranges from 80 ppm to 260 ppm.

In an embodiment, the chlorine content of the chlorine-containing impurities ranges from 80 ppm to 90 ppm.

In an embodiment, the total weight of the electrically insulating but thermally conductive layer is calculated as 100%, and the epoxy-based composition accounts for 10% to 40% and the thermally conductive filler accounts for 60% to 90%.

In an embodiment, the total weight of the electrically insulating but thermally conductive layer is calculated as 100%, and the epoxy-based composition accounts for 30% to 40% and the thermally conductive filler accounts for 60% to 70%.

In an embodiment, the thermally conductive board has a service life more than 200 hours under a harsh environment, wherein the harsh environment includes a high temperature of 85° C., a relative humidity of 85%, and a DC voltage of 1 kV.

In an embodiment, the service life ranges from 200 hours to 900 hours.

In an embodiment, the service life ranges from 800 hours to 900 hours.

In an embodiment, the thermally conductive board has an adhesion strength ranging from 1 kg/cm to 2.1 kg/cm.

In an embodiment, the thermally conductive filler is selected from the group consisting of zirconium nitride, boron nitride, aluminum nitride, silicon nitride, aluminum oxide, magnesium oxide, zinc oxide, silicon dioxide, titanium dioxide, and any combination thereof.

In an embodiment, the electrically insulating but thermally conductive layer does not include a glass fiber.

In an embodiment, the epoxy-based composition has a glass transition temperature (T_{g}) of at least 130° C.

In an embodiment, the top metal layer has a thickness ranging from 0.01 mm to 3 mm, and the bottom metal layer has a thickness ranging from 0.1 mm to 3 mm.

In an embodiment, the electrically insulating but thermally conductive layer has a thickness ranging from 0.03 mm to 0.3 mm.

### BRIEF DESCRIPTION OF THE DRAWINGS

The present application will be described according to the appended drawings in which:

FIG. 1 shows a cross-sectional view of a thermally conductive board in accordance with an aspect of the present invention; and

FIG. 2 shows a cross-sectional view of a thermally conductive board in accordance with another aspect of the present invention.

### DETAILED DESCRIPTION OF THE INVENTION

The making and using of the presently preferred illustrative embodiments are discussed in detail below. It should be appreciated, however, that the present application provides many applicable inventive concepts that can be embodied in a wide variety of specific contexts. The specific illustrative embodiments discussed are merely illustrative of specific ways to make and use the invention, and do not limit the scope of the invention.

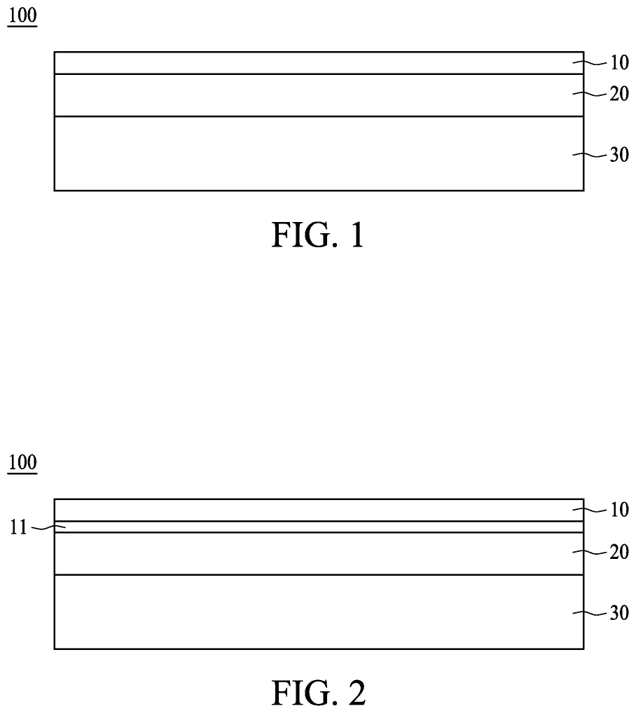

Please refer to FIG. 1, which shows a cross-sectional view of a thermally conductive board 100 of the present invention. The thermally conductive board 100 of the present invention includes a top metal layer 10, a bottom metal layer 30, and an electrically insulating but thermally conductive layer 20 (referred to as “thermally conductive layer” hereinafter for simplification). The thermally conductive layer 20 physically contacts the top metal layer 10 and the bottom metal layer 30, and is laminated therebetween, forming a triple-layer structure. Preferably, the top metal layer 10 is made of copper foil or copper plate, and the bottom metal layer 30 is made of aluminum plate or copper plate. Because of the thermally conductive layer 20, the top metal layer 10 is electrically isolated from the bottom metal layer 30. In an embodiment, the top metal layer 10 has a thickness ranging from 0.01 mm to 3 mm; the bottom metal layer 30 has a thickness ranging from 0.1 mm to 3 mm; and the thermally conductive layer 20 has a thickness ranging from 0.03 mm to 0.3 mm. The top metal layer 10 can be subsequently processed to form a wiring layer to be assembled with various electronic components, while the bottom metal layer 30 serves as a base substrate for thermal conduction, facilitating the dissipation of heat to the external environment. In an embodiment, both the top metal layer 10 and the bottom metal layer 30 are made of copper foil or copper plate, both of which may be processed into the wiring layers, forming a double-sided circuit board. In another embodiment, the top metal layer 10 is copper foil, and the bottom metal layer 30 is a metal plate made without copper, such as aluminum plate. Moreover, the thermally conductive board 100 with double-sided copper foil/plate can optionally be processed into a single-sided circuit board, a double-sided circuit board, or other types of circuit board depending on the requirements. Besides the wiring layer or the metal base substrate, thermally conductive layer 20 is excellent in thermal conduction, and therefore heat produced from the electronic components can be effectively transferred from the thermally conductive layer 20 to any metal layer for heat dissipation. The thermally conductive layer 20 includes a polymer matrix and a thermally conductive filler. The polymer matrix provides the thermally conductive layer 20 with excellent electrical insulation, and the thermal conductivity of the thermally conductive layer 20 is enhanced by adding the thermally conductive filler.

In the present invention, the major constituent of the polymer matrix is an epoxy-based composition. When the chlorine content of the thermally conductive layer 20 is less than 300 ppm, the thermally conductive board 100 can exhibit excellent electrical characteristics. It is known that chlorine-containing impurities are unavoidably generated during any epoxy synthesis process, and, hence, there is no guarantee of 100% purity of epoxy in practical use. More specifically, the raw materials for synthesizing epoxy include epichlorohydrin and a dihydric phenol (e.g., bisphenol A, bisphenol S, bisphenol F, or other bisphenols), and the epoxy with a specific purity can be obtained through a ring-opening reaction, dechlorination, and other steps based on these two materials. However, the chlorine from epichlorohydrin leads to several chlorine-containing by-products during the aforementioned processes, and it cannot be completely removed through washing, precipitation, or other means. Moreover, a residual amount of epichlorohydrin may still exist due to incomplete reactions. The aforementioned chlorine-containing impurities generally consists of the chlorine-containing by-products and the residual amount of epichlorohydrin (i.e., unreacted epichlorohydrin). The epoxy-based composition in the present disclosure is substantially defined as epoxy without 100% purity.

The present invention finds that the weather resistance of the thermally conductive board 100 can be enhanced, especially during high temperature high humidity bias test (HHBT), as the chlorine content of chlorine-containing impurities decreases to an extremely low level. This is because the chlorine content is strongly related to copper ion migration. In the test of HHBT, the thermally conductive board 100 is applied with a direct current, creating an electric field between the top metal layer 10 and the bottom metal layer 30. In the meantime, the top metal layer 10 and the bottom metal layer 30 may be referred to as two electrodes in a reduction-oxidation reaction. For example, the top metal layer 10 serves as anode, and the bottom metal layer 30 serves as cathode. At the anode, copper is oxidized to copper ions, as shown below in the equation: Cu→Cu²⁺+2e⁻. At the cathode, copper ions are reduced to copper, as shown below in the equation: Cu²⁺+2e⁻→Cu. Under the effect of the electric field, copper ions at the anode would gradually pass through the thermally conductive layer 20 and migrate to the cathode, leading to electrical insulation failure of the thermally conductive layer 20 and eventually resulting in a short-circuit problem. It is noted that the amount of chlorine in the thermally conductive layer 20 positively correlates with the corrosion rate of copper, i.e., the oxidization rate at the anode mentioned earlier. Chlorine ions in the thermally conductive layer 20 may react with copper at the anode to produce copper chloride, as shown in the equation: 2Cu+4Cl⁻⇄2CuCl²⁻+2e⁻. Then, the copper chloride may dissociate and react with O₂ to give Cu²⁺. From the above, it is observed that the higher the chlorine content, the greater the generation of copper ions. During HHBT, an excessive amount of chlorine results in a more pronounced phenomenon of copper ion migration, ultimately leading to the electrical insulation failure of the thermally conductive layer 20 and causing the burnout of the thermally conductive board 100. Besides the issue of the aforementioned copper ion migration, the chlorine-containing impurities may be transformed into hydrogen chloride or hypochlorous acid during the manufacturing processes, thereby eroding the wiring layer. In other words, the chlorine-containing impurities also compromise the performance of the thermally conductive board 100 in the subsequent circuit design.

The aforementioned HHBT is an accelerated aging test used to simulate a harsh environment with a high temperature of 85° C., a relative humidity of 85%, and a DC voltage of 1 kV. A service life of device obtained from this test is also helpful in estimating an actual service life under normal temperature and pressure conditions. In an embodiment, in order to increase the service life to 200 hours to 900 hours, the chlorine content of the chlorine-containing impurities is controlled within a range of 80 ppm to 260 ppm. In a preferred embodiment, in order to increase the service life to 800 hours to 900 hours, the chlorine content of the chlorine-containing impurities is controlled within a range of 80 ppm to 90 ppm. In the present invention, the total weight of the thermally conductive layer 20 is calculated as 100%, and the epoxy-based composition accounts for 10% to 40% and the thermally conductive filler accounts for 60% to 90%. In some cases, a higher proportion of the epoxy-based composition is required. The present invention may increase the weight percentage of the epoxy-based composition while still maintaining an extremely low chlorine content of chlorine-containing impurities. Therefore, the thermally conductive board 100 with a higher proportion of the epoxy-based composition still has a longer service life compared to the conventional one. For example, in one embodiment, the total weight of the thermally conductive layer 20 is calculated as 100%, and the epoxy-based composition accounts for 30% to 40% and the thermally conductive filler accounts for 60% to 70%, wherein the chlorine content in the epoxy-based composition is less than 90 ppm.

Moreover, the polymer matrix further includes a polymer modifier, which can improve the impact resistance of the epoxy-based composition. The polymer modifier is selected from the group consisting of phenoxy resin, polysulfone, polyethersulfone, polystyrene, polyphenylene oxide, polyphenylene sulfide, polyamide, polyimide, polyetherimide, polyetherimide/silicone block copolymer, polyurethane, polyester, polycarbonate, polymethyl methacrylate, styrene/acrylonitrile, styrene block copolymers, and any combination thereof.

As for the thermally conductive filler, the present invention does not use any glass fiber in the thermally conductive layer 20 due to its poor thermal conductivity, and the present invention doesn't need the additional structural support provided by the glass fiber. That is, the thermally conductive layer 20 of the present invention does not include a glass fiber. The thermally conductive filler of the present invention is selected from the group consisting of zirconium nitride, boron nitride, aluminum nitride, silicon nitride, aluminum oxide, magnesium oxide, zinc oxide, silicon dioxide, titanium dioxide, and any combination thereof. In a preferred embodiment, the thermally conductive filler of the present invention is aluminum oxide. In cases where the chlorine content of chlorine-containing impurities is extremely low, the use of aluminum oxide as the thermal conductive filler can further enhance the thermal conduction of the thermally conductive board 100, resulting in the thermally conductive board having a coefficient of thermal conductivity ranging from 2.4 W/mk to 2.7 W/mk.

In the present invention, a glass transition temperature (T_{g}) of the epoxy-based composition is at least 130° C. The glass transition temperature (T_{g}) is a temperature point at which the epoxy-based composition transitions between a glassy state and a rubbery state. In an embodiment, a glass transition temperature (T_{g}) of the epoxy-based composition ranges from 130° C. to 350° C. If the glass transition temperature is too low (i.e., below 130° C.), the epoxy-based composition is easily softened under a low temperature condition. This leads to structural instability of the thermally conductive board 100, thereby compromising its performance in HHBT and its applicability. If the glass transition temperature is too high (i.e., above 350° C.), the epoxy-based composition would have excessively high hardness after curing, which is unfavorable for its machining or molding processes after curing.

To further verify the performance of thermally conductive board 100 of the present invention, various tests were conducted and the results are shown in Table 1.

TABLE 1

| | Chlorine | Adhesion | Coefficient of thermal | |
|---|---|---|---|---|
| | content | strength | conductivity | HHBT |
| Group | (ppm) | (kg/cm) | (W/mk) | (hour) |
| C1 | 400 | 1.5 | 2.2 | 89 |
| E1 | 251 | 1.7 | 2.4 | 224 |
| E2 | 150 | 1.9 | 2.5 | 570 |
| E3 | 85.4 | 2.1 | 2.7 | 899 |
| E4 | 88.5 | 2.3 | 2.5 | 800 |

As shown in Table 1, groups E1 to E4 represent embodiments E1 to E4 of the present invention, and group C1 represents comparative example C1. In each one of the embodiments E1 to E4, the size of the thermally conductive board 100 is “10 mm×10 mm” in top view; the top metal layer 10 is made of copper foil with a thickness of 0.035 mm, and the bottom metal layer 30 is made of aluminum plate with a thickness of 1.5 mm; and the thermally conductive layer 20 has a thickness of 0.1 mm, and consists of epoxy which is not 100% pure (i.e., the epoxy-based composition as previously mentioned) and aluminum oxide (i.e., the thermally conductive filler as previously mentioned). The total weight of the thermally conductive layer 20 is calculated as 100%. In the embodiments E1 to E3, the epoxy-based composition accounts for 15%, and aluminum oxide accounts for 85%. In the embodiment E4, the epoxy-based composition accounts for 30%, and aluminum oxide accounts for 70%. The top-view size, composition of top/bottom metal layers, thickness of each layer, and proportion of epoxy/aluminum oxide in the comparative example C1 are the same as those in the embodiments E1 to E3. The difference between the comparative example C1 and the embodiments E1 to E3 lies in the chlorine content.

“Chlorine content” refers to the chlorine content in the thermally conductive layer, and the chlorine substantially comes from the impure epoxy (i.e., the epoxy-based composition). As mentioned earlier, epoxy-based composition consists of epoxy and chlorine-containing impurities. In other words, the epoxy-based composition unavoidably contains a certain level of chlorine impurities, aside from epoxy itself, leading to an excessively high chlorine content in the thermally conductive layer. The chlorine content can be measured through any standard technique. In the present disclosure, inductively coupled plasma optical emission spectroscopy (ICE-OES) is used to measure the chlorine content in the thermally conductive layer.

“Adhesion strength,” also known as peel strength, is the force needed to separate the top metal layer (or the bottom metal layer) from the thermally conductive layer.

“Coefficient of thermal conductivity,” also simply known as thermal conductivity, is defined as the ability of a material to conduct heat. The general formula of thermal conductivity is k=(Q/t)*L/(A*ΔT). “k” is thermal conductivity (W/mk); “Q” is amount of heat (W); “t” is time; “L” is length (m); “A” is area of cross section (m²); and “ΔT” is temperature difference. The thermal conductivity of the thermally conductive board is measured in accordance with the standard of ASTM D5470.

“HHBT” stands for High Temperature High Humidity Bias Test. This test is used to simulate a device's lifetime under a harsh environment involving high temperature, high humidity, and high voltage. A sample to be tested (i.e., the thermally conductive board) is applied with a DC (direct current) voltage of 1 kV in an environment with a temperature of 85° C. and relative humidity of 85%. The tested sample will ultimately be burnt out due to the applied DC voltage over hours, allowing for the evaluation of its service life in such accelerated aging test.

As shown in Table 1, the chlorine content in the epoxy-based composition significantly affects the endurable time (in unit of hour) in HHBT, and its effect also reflects on the adhesion strength and thermal conductivity. Regarding HHBT, as the chlorine content in the thermally conductive layer decreases from 251 ppm in the embodiment E1 to 85.4 ppm in the embodiment E3, the duration of HHBT correspondingly increases from 224 hours to 899 hours. This shows that an increased presence of chlorine is more likely to accelerate the phenomenon of copper ion migration, leading to electrical insulation failure of the thermally conductive layer and its burnout. In contrast, the chlorine content of the comparative example C1 reaches 400 ppm, resulting in a much shorter duration in HHBT, i.e., 89 hours. Regarding adhesion strength, an excessive amount of chlorine affects the curing of epoxy, resulting in a lack of tight bonding at the interface between the thermally conductive layer and metal layer, that is, poor adhesion therebetween. As a result, the adhesion strength in the comparative example C1 (i.e., 1.5 kg/cm) is lower than the adhesion strength in the embodiments E1 to E3 (i.e., 1.7 kg/cm to 2.1 kg/cm). Considering the measurement error and the permissible error in practical use, the adhesion strength in the embodiments E1 to E4 of the present invention generally varies within the range of 1 kg/cm to 2.5 kg/cm. It is worth mentioning that the present disclosure also finds that the thermal conductivity of the thermally conductive board can be further improved as it contains an extremely low chlorine content. In the embodiments E1 to E3, the thermal conductivity is in the range of 2.4 W/mk to 2.7 W/mk, which is higher than the thermal conductivity of the comparative example C1 (i.e., 2.2 W/mk).

It is noted that, in some cases, the proportion of the epoxy-based composition in the thermally conductive layer 20 may be increased in order to effectively enhance electrical insulation or meet other requirements. Therefore, in the embodiment E4, the proportion of the epoxy-based composition is deliberately increased to simulate the aforementioned situation. Likewise, the duration in HHBT in the embodiment E4 is higher than that in the comparative example C1 and reaches 800 hours, and improvements are also observed in the adhesion strength and thermal conductivity in the embodiment E4.

Please refer to FIG. 2, which illustrates a thermally conductive board 100 in accordance with another aspect of the present invention. In FIG. 2, the top metal layer 10, the bottom metal layer 30, and the thermally conductive layer 20 have been thoroughly discussed previously, and are not described in detail herein. The difference between FIG. 2 and FIG. 1 is that FIG. 2 additionally includes a metal coating layer 11. To further address the issue of copper ion migration, the metal coating layer 11 with a thickness of 1 μm to 10 μm can be plated on the bottom surface of the top metal layer 10. That is, the thermally conductive board 100 further includes the metal coating layer 11. The metal coating layer 11 is disposed between the top metal layer 10 and the thermally conductive layer 20, and is in physical contact with the top metal layer 10. The metal coating layer 11 is made from a material selected from the group consisting of nickel, tin, zinc, chromium, bismuth, cobalt, and any combination thereof. In a preferred embodiment, the metal coating layer 11 is made of nickel. The metal coating layer 11 not only serves as a physical barrier but also exhibits better chemical inertness. In this way, it is difficult for copper ions to penetrate from the top metal layer 10 to the thermally conductive layer 20 through the metal coating layer 11, thereby further enhancing the service life of the thermally conductive board 100. It is noted that, in general, although the addition of the metal coating layer 11 is helpful in impeding the migration of copper ions, it may lead to an increase in the heat resistance of the thermally conductive board 100 (i.e., a decrease in its thermal conductivity). However, the present invention finds that this disadvantage can be mitigated by reducing the chlorine content in the epoxy-based composition, and in the meantime, the endurable time (in unit of hour) in HHBT can be significantly elongated.

The above-described embodiments of the present invention are intended to be illustrative only. Numerous alternative embodiments may be devised by persons skilled in the art without departing from the scope of the following claims.

What is claimed is:

1. A thermally conductive board, comprising:
a top metal layer;
a bottom metal layer; and
an electrically insulating but thermally conductive layer laminated between the top metal layer and the bottom metal layer, and comprising a polymer matrix and a thermally conductive filler dispersed in the polymer matrix, wherein:
the polymer matrix comprises an epoxy-based composition consisting of epoxy and chlorine-containing impurities, wherein the epoxy is the main product obtained by a synthesis process using epichlorohydrin and a dihydric phenol as raw materials, and the chlorine-containing impurities are the unreacted epichlorohydrin and by-products produced from the synthesis process; and
the chlorine-containing impurities has a chlorine content less than 300 ppm.

2. The thermally conductive board of claim 1, wherein the chlorine content of the chlorine-containing impurities ranges from 80 ppm to 260 ppm.

3. The thermally conductive board of claim 2, wherein the chlorine content of the chlorine-containing impurities ranges from 80 ppm to 90 ppm.

4. The thermally conductive board of claim 1, wherein the total weight of the electrically insulating but thermally conductive layer is calculated as 100%, and the epoxy-based composition accounts for 10% to 40% and the thermally conductive filler accounts for 60% to 90%.

5. The thermally conductive board of claim 4, wherein the total weight of the electrically insulating but thermally conductive layer is calculated as 100%, and the epoxy-based composition accounts for 30% to 40% and the thermally conductive filler accounts for 60% to 70%.

6. The thermally conductive board of claim 1, wherein the thermally conductive board has a service life more than 200 hours under a harsh environment, wherein the harsh environment includes a high temperature of 85° C., a relative humidity of 85%, and a DC voltage of 1 kV.

7. The thermally conductive board of claim 6, wherein the service life ranges from 200 hours to 900 hours.

8. The thermally conductive board of claim 7, wherein the service life ranges from 800 hours to 900 hours.

9. The thermally conductive board of claim 1, wherein the thermally conductive board has an adhesion strength ranging from 1 kg/cm to 2.1 kg/cm.

10. The thermally conductive board of claim 1, wherein the thermally conductive filler is selected from the group consisting of zirconium nitride, boron nitride, aluminum nitride, silicon nitride, aluminum oxide, magnesium oxide, zinc oxide, silicon dioxide, titanium dioxide, and any combination thereof.

11. The thermally conductive board of claim 1, wherein the electrically insulating but thermally conductive layer does not comprise a glass fiber.

12. The thermally conductive board of claim 1, wherein the epoxy-based composition has a glass transition temperature (T_{g}) of at least 130° C.

13. The thermally conductive board of claim 1, wherein the top metal layer has a thickness ranging from 0.01 mm to 3 mm, and the bottom metal layer has a thickness ranging from 0.1 mm to 3 mm.

14. The thermally conductive board of claim 1, wherein the electrically insulating but thermally conductive layer has a thickness ranging from 0.03 mm to 0.3 mm.
